(19) United States
(12) Patent Application Publication
(10) Pub. No.: US 2025/0199367 A1
(43) Pub. Date: Jun. 19, 2025

(54) DISPLAY PANELS AND DISPLAY DEVICES

(71) Applicant: Guangzhou China Star Optoelectronics Semiconductor Display Technology Co., Ltd., Guangzhou (CN)

(72) Inventors: Yunlong LI, Guangzhou (CN); Xiaobo ZHOU, Guangzhou (CN)

(73) Assignee: Guangzhou China Star Optoelectronics Semiconductor Display Technology Co., Ltd., Guangzhou (CN)

(21) Appl. No.: 18/542,680

(22) Filed: Dec. 17, 2023

(30) Foreign Application Priority Data
Jul. 26, 2023 (CN) 202310928977.9

(51) Int. Cl. G02F 1/1343; G02F 1/13357

(52) U.S. Cl. CPC G02F 1/13439; G02F 1/133603; G02F 2201/123

(57) ABSTRACT

A display panel and a display device are provided by the present disclosure. The display panel includes a substrate, a plurality of conductive connectors, and a plurality of miniature light emitting diodes. The substrate includes a base and a plurality of solder pad terminals disposed on the base. The conductive connectors are disposed on the plurality of the solder pad terminals. The miniature light emitting diodes include a plurality of connection terminals. The plurality of the miniature light emitting diodes are electrically connected to corresponding ones of the solder pad terminals through the conductive connectors. The conductive connectors include a thermoplastic material and a conductive material distributed in the thermoplastic material.

### CROSS-REFERENCE TO RELATED APPLICATION

The present disclosure claims priority to and the benefit of Chinese Patent Application No. 202310928977.9, filed on Jul. 26, 2023, the disclosure of which is incorporated herein by reference in its entirety.

### TECHNICAL FIELD

The present disclosure relates to display technologies, and in particular to display panels and display devices.

### BACKGROUND

Miniature light-emitting diodes (mini light-emitting diodes or micro light-emitting diodes) have been used in display panel. For example, mini light-emitting diodes are used as the backlight for liquid crystal display panels, or micro light-emitting diode display panels are used as outdoor displays. In the manufacturing process of miniature light-emitting diode display panels, it is necessary to solder the miniature light-emitting diodes to the solder pad terminals on the substrate by solder.

However, in existing technology, when the miniature light-emitting diodes are repaired and peeled off from the substrate, it is easy to remove the metal from the solder pad terminals on the substrate, resulting in substrate damage and making it impossible to perform miniature light-emitting diode solder repair again.

### SUMMARY

The embodiments of the present disclosure provide a display panel. The display panel includes includes a substrate, a plurality of conductive connectors, and a plurality of miniature light emitting diodes. The substrate includes a base and a plurality of solder pad terminals disposed on the base. The conductive connectors are disposed on the plurality of the solder pad terminals. The miniature light emitting diodes include a plurality of connection terminals. The connection terminals are electrically connected to corresponding ones of the solder pad terminals through the conductive connectors. The conductive connectors include a thermoplastic material and a conductive material distributed in the thermoplastic material.

Correspondingly, the present disclosure further provides a display device. The display device includes a liquid crystal display panel and a backlight. The backlight includes a substrate, a plurality of conductive connectors, and a plurality of miniature light emitting diodes. The substrate includes a base and a plurality of solder pad terminals disposed on the base. The conductive connectors are disposed on the plurality of the solder pad terminals. The miniature light emitting diodes include a plurality of connection terminals. The connection terminals are electrically connected to corresponding ones of the solder pad terminals through the conductive connectors. The conductive connectors include a thermoplastic material and a conductive material distributed in the thermoplastic material.

### BRIEF DESCRIPTION OF THE DRAWINGS

To describe the technical solutions of the embodiments of the present disclosure more clearly, the following briefly introduces the accompanying drawings used in the description of the embodiments of the present disclosure. Apparently, the accompanying drawings described below illustrate only some exemplary embodiments of the present disclosure, and persons skilled in the art may derive other drawings from the drawings without making creative efforts.

FIG. 1 is a schematic view of a display panel provided by an embodiment of the present disclosure.

FIG. 2 is a schematic view of miniature light-emitting diode peeling provided by the prior art.

FIG. 3 is a schematic view of miniature light-emitting diode peeling by an embodiment provided by the present disclosure.

### DETAILED DESCRIPTION

The technical solutions in the embodiments of the present disclosure will be described clearly and completely hereafter with reference to the accompanying drawings. Apparently, the described embodiments are only a part of but not all embodiments of the present disclosure. All other embodiments obtained by persons of ordinary skill in the art based on the embodiments of the present disclosure without creative efforts shall fall in the protection scope of the present disclosure. In addition, it should be understood that the specific embodiments described herein are merely for illustrating and explaining the present disclosure, and not intended to limit the present disclosure. In the present disclosure, unless stated to the contrary, the used orientation words such as “up” and “down” generally refer to up and down in the actual use or working state of the device, specifically the direction of the drawing in the accompany drawings, and “inside” and “outside” are relative to the outline of the device.

The embodiments of the present disclosure provide a display panel and a display device. The display panel includes a substrate, a plurality of conductive connectors, and a plurality of miniature light emitting diodes. The substrate includes a base and a plurality of solder pad terminals disposed on the base. The conductive connectors are disposed on the plurality of the solder pad terminals. The miniature light emitting diodes include a plurality of connection terminals. The connection terminals are electrically connected to corresponding ones of the solder pad terminals through the conductive connectors. The conductive connectors include a thermoplastic material and a conductive material distributed in the thermoplastic material.

Detailed explanations will be provided below. It should be noted that the description order of the following embodiments does not serve as a limitation on the preferred order of embodiments.

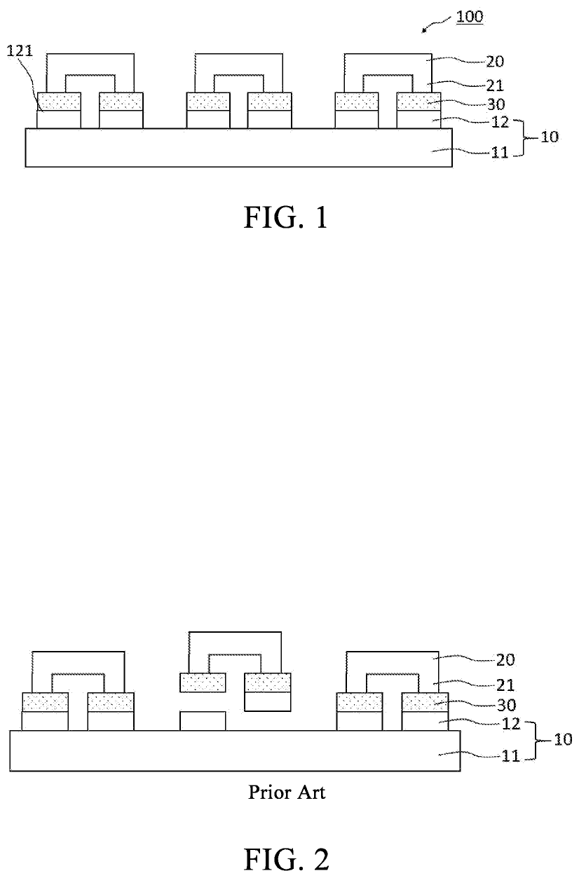

Referring to FIG. 1, which is a schematic view of a display panel provided by an embodiment of the present disclosure.

The present disclosure provides a display panel 100, which includes a substrate 10, a plurality of conductive connectors 30, and a plurality of miniature light emitting diodes 20. The substrate 10 includes a base 11 and a plurality of solder pad terminals 12 disposed on the base 11. The plurality of the conductive connectors 30 are disposed on the plurality of the solder pad terminals 12. The plurality of the miniature light emitting diodes 20 include a plurality of connection terminals 21, and the connection terminals 21 are electrically connected to the corresponding solder pad terminals 12 through conductive connectors 30. The conductive connector 30 includes a thermoplastic material and a conductive material distributed in the thermoplastic material.

Specifically, FIG. 1 shows that a pair of the solder pad terminals 12 include a first sub solder pad terminal and a second sub solder pad terminal. The miniature light-emitting diode 20 includes a pair of connection terminals 21, which includes a first sub connection terminal and a second sub connection terminal. The first sub connection terminal may be one of a positive electrode and a negative electrode, and the second sub connection terminal may be another one of the positive electrode and the negative electrode. The first sub solder pad terminal and the second sub solder pad terminal are connected to the first sub connection terminal and the second sub connection terminal through different conductive connectors 30, respectively.

In the embodiment, the conductive connector 30 replaces the solder of the prior art. As the conductive connector 30 includes a thermoplastic material and a conductive material distributed in the thermoplastic material. the thermoplastic material is capable of transitioning to a molten state at lower temperatures. When the miniature light-emitting diodes 20 are repaired and peeled off from the substrate 10, the solder pad terminals 12 on the substrate 10 may be not taken away, ensuring that the substrate 10 is undamaged, and solder repairs on the miniature light-emitting diodes 20 may be performed again.

In the embodiment, due to the transition of thermoplastic material to a molten state at lower temperatures, even if a thickness of the solder pad terminal 12 is small the miniature light-emitting diodes 20 will not take away the solder pad terminals 12 made of conductive materials such as copper on the substrate 10, when repaired and peeled off from the substrate 10. So that, the substrate 10 may be ensured to be undamaged for further solder repair of the miniature light-emitting diodes 20. Thus, another good miniature light emitting diodes 20 can be soldered onto the solder pad terminals 12.

In some embodiments, the conductive material is black in color.

Specifically, the solder pad terminals 12 are made of metal materials, which may reflect ambient light. The conductive material is black in color, making the conductive connector 30 also black in color. The conductive connectors 30 are disposed on the solder pad terminals 12, which can prevent the solder pad terminals 12 from reflecting ambient light, thereby improving the visibility of the display panel 100.

In some embodiments, the conductive material includes at least one of carbon nanotubes, graphene, MXene, iron black, pyrrole, or aniline.

In some embodiments, the conductive material further includes silver powder or tin powder.

Specifically, silver power or tin powder is used to increase the conductivity of the conductive connector 30.

In some embodiments, the conductive material may be a mixture of black conductive material and silver or tin powder, which is used to enhance the conductivity of the conductive material.

In some embodiments, a melting point of the thermoplastic material is less than or equal to 200 degrees Celsius.

Specifically, when the melting point of thermoplastic material is less than or equal to 200 degrees Celsius, the thermoplastic material is capable of transitioning to a molten state at lower temperatures, and the miniature light-emitting diode 20 is easily peeled off from the substrate 10 during repair.

Specifically, the preferred melting point of thermoplastic material range from 100 degrees Celsius to 200 degrees Celsius.

In some embodiments, the thermoplastic material includes at least one of epoxy resin, polypropylene, polymethyl methacrylate, or polyethylene terephthalate.

In some embodiments, the thermoplastic material is a thermal curing material or an ultraviolet curing material.

Specifically, when soldering the miniature light-emitting diode 20 with the solder pad terminal 12 through the conductive connector 30, cooling may be used to convert the conductive connector 30 into a solid state, or a thermal curing material or an ultraviolet curing material may be used as the thermoplastic material to convert the conductive connector 30 into a solid state by thermal curing or ultraviolet curing.

Specifically, thermal curing or ultraviolet curing may cause a polymerization reaction of the thermoplastic material, and the conductive connectors formed by the polymerization reaction are thermoplastic.

In some embodiments, the conductive connectors cover the solder pad terminals 12.

Specifically, as shown in FIG. 1, an area or a size of the solder pad terminal 12 may be larger than that of the connection terminal 21. The conductive connector covers the solder pad terminal 12, which can prevent all surface 121 of the solder pad terminal 12 from reflecting ambient light.

In some embodiments, the substrate 10 further includes a plurality of driving circuits that drive the corresponding miniature light-emitting diodes 20 to emit light.

Specifically, the miniature light-emitting diodes 20 can be driven by driving circuits to emit light stably.

In some embodiments, the plurality of the miniature light emitting diodes 20 are used as light sources of backlighting of the display panel 100 or as sub pixels for display image.

Specifically, the display panel 100 may serve as the backlight for the liquid crystal display panel. The miniature light emitting diodes 20 may serve as display pixels to directly display images, and there is no limitation here.

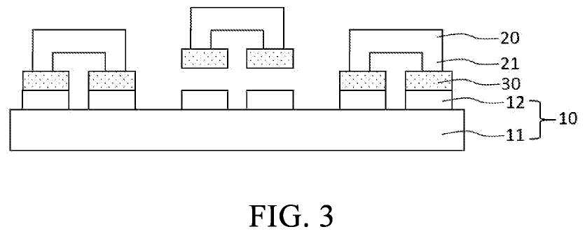

Referring to FIGS. 2 and 3, FIG. 2 is a schematic view of miniature light-emitting diode peeling provided by the prior art. FIG. 3 is a schematic view of miniature light-emitting diode peeling by an embodiment provided by the present disclosure. From FIG. 2, it can be seen that in the prior art, when the miniature light-emitting diode 20 is repaired and peeled off from the substrate 10, it is easy to take away the metal of the solder pad terminal 12 on the substrate 10, resulting in damage to the substrate 10, and it is impossible to solder and repair the miniature light-emitting diode 20 again. From FIG. 3, it can be seen that in the embodiment of the present disclosure, the conductive connector 30 replaces the solder of the prior art. As the conductive connector 30 includes thermoplastic materials and conductive materials distributed in the thermoplastic materials, the thermoplastic materials transform into a molten state at lower temperatures. When the miniature light-emitting diode 20 is repaired and peeled off from the substrate 10, it will not take away the solder pad terminal 12 on the substrate 10, thereby ensuring that the substrate 10 is undamaged, so that the solder repairs on the micro light-emitting diode 20 is capable of being performed again.

It should be noted that the present disclosure utilizes a high-temperature blend of black conductive materials and thermoplastic materials to form a conductive black thermoplastic composite material, which is attached to the solder pad terminal as a solder. By utilizing the thermoplastic properties of the solder, it can become a molten state at low temperatures (around 100-200° C.), achieving the peeling of light-emitting diode (LED) chips and effectively protecting substrate organic matter and the solder pad terminals. In addition, the solder cools down and restores its solid state, achieving the adhesion of LED chips. Therefore, multiple repeated miniature light-emitting diode repairs can be achieved, ensuring display performance. The present disclosure proposes the use of conductive connectors 30 with thermoplastic properties to solder the LED chips, in order to achieve a reversible solder scheme multiple times without damage to the solder pads terminals.

Correspondingly, the present disclosure further provides a display device, which includes a liquid crystal display panel and a backlight. The backlight includes a substrate 10, a plurality of conductive connectors 30, and a plurality of miniature light emitting diodes 20. The substrate 10 includes a base 11 and a plurality of solder pad terminals 12 disposed on the base 11. The plurality of the conductive connectors 30 are disposed on the plurality of the solder pad terminals 12. The plurality of the miniature light emitting diodes 20 include a plurality of connection terminals 21, and the connection terminals 21 are electrically connected to the corresponding solder pad terminals 12 through conductive connectors 30. The conductive connector 30 includes a thermoplastic material and a conductive material distributed in the thermoplastic material.

Specifically, the backlight may include any of the features of the display panel 100 mentioned above.

The display panel and the display device provided in the embodiments of the present disclosure are described in detail above. The principle and implementations of the present disclosure are described in this specification by using specific examples. The description about the foregoing embodiments is merely provided to help understand the method and core ideas of the present disclosure. In addition, persons of ordinary skill in the art can make modifications in terms of the specific implementations and application scopes according to the ideas of the present disclosure. Therefore, the content of this specification shall not be construed as a limit to the present disclosure.

What is claimed is:

1. A display panel, comprising:
a substrate, comprising a base and a plurality of solder pad terminals disposed on the base;
a plurality of conductive connectors disposed on the plurality of the solder pad terminals; and
a plurality of miniature light emitting diodes comprising a plurality of connection terminals, wherein the connection terminals are electrically connected to corresponding ones of the solder pad terminals through the conductive connectors;
wherein the conductive connectors comprise a thermoplastic material and a conductive material distributed in the thermoplastic material.

2. The display panel of claim 1, wherein the conductive material is black in color.

3. The display panel of claim 2, wherein the conductive material comprises at least one of carbon nanotubes, graphene, MXene, iron black, pyrrole, or aniline.

4. The display panel of claim 3, wherein the conductive material further comprises silver powder or tin powder.

5. The display panel of claim 2, wherein a melting point of the thermoplastic material is less than or equal to 200 degrees Celsius.

6. The display panel of claim 5, wherein the melting point of the thermoplastic material ranges from 100 degrees Celsius to 200 degrees Celsius.

7. The display panel of claim 2, wherein the thermoplastic material comprises at least one of epoxy resin, polypropylene, polymethyl methacrylate, or polyethylene terephthalate.

8. The display panel of claim 2, wherein the thermoplastic material is a thermal curing material or an ultraviolet curing material.

9. The display panel of claim 2, wherein the conductive connectors cover the solder pad terminals.

10. The display panel of claim 1, wherein the substrate further comprises a plurality of driving circuits, and the driving circuits drive corresponding ones of the miniature light-emitting diodes to emit light.

11. A display device, comprising a liquid crystal display panel and a backlight, wherein the backlight comprises:
a substrate, comprising a base and a plurality of solder pad terminals disposed on the base;
a plurality of conductive connectors disposed on the plurality of the solder pad terminals; and
a plurality of miniature light emitting diodes comprising a plurality of connection terminals, wherein the connection terminals are electrically connected to corresponding ones of the solder pad terminals through the conductive connectors;
wherein the conductive connectors comprise a thermoplastic material and a conductive material distributed in the thermoplastic material.

12. The display device of claim 11, wherein the conductive material is black in color.

13. The display device of claim 12, wherein the conductive material comprises at least one of carbon nanotubes, graphene, MXene, iron black, pyrrole, or aniline.

14. The display device of claim 13, wherein the conductive material further comprises silver powder or tin powder.

15. The display device of claim 12, wherein a melting point of the thermoplastic material is less than or equal to 200 degrees Celsius.

16. The display device of claim 15, wherein the melting point of the thermoplastic material ranges from 100 degrees Celsius to 200 degrees Celsius.

17. The display device of claim 12, wherein the thermoplastic material comprises at least one of epoxy resin, polypropylene, polymethyl methacrylate, or polyethylene terephthalate.

18. The display device of claim 12, wherein the thermoplastic material is a thermal curing material or an ultraviolet curing material.

19. The display device of claim 12, wherein the conductive connectors cover the solder pad terminals.

20. The display device of claim 11, wherein the substrate further comprises a plurality of driving circuits, and the driving circuits drive corresponding ones of the miniature light-emitting diodes to emit light.
